(19) United States
(12) Patent Application Publication
(10) Pub. No.: US 2026/0231462 A1
(43) Pub. Date: Aug. 6, 2026

(54) SEMICONDUCTOR DEVICE AND METHOD OF MANUFACTURING SEMICONDUCTOR DEVICE

(71) Applicant: SUMITOMO ELECTRIC DEVICE INNOVATIONS, INC., Kanagawa (JP)

(72) Inventor: Atsuya SASAKI, Kanagawa (JP)

(21) Appl. No.: 19/459,519

(22) Filed: Jan. 26, 2026

(30) Foreign Application Priority Data
Feb. 4, 2025 (JP) 2025-016910

(51) Int. Cl. H10D 30/47; H10D 30/01; H10D 62/85; H10W 20/00; H10W 20/20

(52) U.S. Cl. CPC H10D 30/475; H10D 30/015; H10D 62/8503; H10W 20/0242; H10W 20/211

(57) ABSTRACT

A semiconductor device includes: a substrate having a first surface and a second surface; a first nitride semiconductor layer having a third surface in contact with the second surface, a fourth surface opposite to the third surface, and a recess formed in the fourth surface; a second nitride semiconductor layer disposed in the recess; a first metal layer disposed on the second nitride semiconductor layer; and a third metal layer. The first metal layer includes a second metal layer containing a platinum group metal. A through-hole penetrates the substrate, the first nitride semiconductor layer, and the second nitride semiconductor layer, and reaches the second metal layer. The third metal layer is in contact with the second metal layer and covers the first surface and an inner wall surface of the through-hole. The second nitride semiconductor layer contains impurity atoms at a concentration of 1.0 × 10¹⁸ cm⁻³ or higher.

### CROSS-REFERENCE TO RELATED APPLICATIONS

This application is based on and claims priority to Japanese Patent Application No. 2025-016910, filed on February 4, 2025, the entire contents of which are incorporated herein by reference.

### TECHNICAL FIELD

The present disclosure relates to a semiconductor device and a method of manufacturing the semiconductor device.

### BACKGROUND

A semiconductor device in which a metal layer in ohmic contact with a semiconductor layer, containing carriers at a high concentration, is formed as an etching stopper on the semiconductor layer is known. In the semiconductor device, a through-hole reaching the etching stopper is formed in the semiconductor layer, and an electrode in contact with the etching stopper is formed in the through-hole. See Japanese Laid-open Patent Publication No. 2024-092747, for example.

### SUMMARY

A semiconductor device according to the present disclosure includes: a substrate having a first surface and a second surface opposite to the first surface; a first nitride semiconductor layer having a third surface in contact with the second surface, and a fourth surface opposite to the third surface, the first nitride semiconductor layer having a recess formed in the fourth surface; a second nitride semiconductor layer disposed in the recess; a first metal layer disposed on the second nitride semiconductor layer; and a third metal layer, wherein the first metal layer includes a second metal layer containing a platinum group metal, a through-hole is formed in the substrate, the first nitride semiconductor layer, and the second nitride semiconductor layer, and the through-hole penetrates the substrate, the first nitride semiconductor layer, and the second nitride semiconductor layer, and reaches the second metal layer, the third metal layer is in contact with the second metal layer and is configured to cover the first surface and an inner wall surface of the through-hole, and the second nitride semiconductor layer contains impurity atoms at a concentration of 1.0 × 10¹⁸ cm⁻³ or higher.

### BRIEF DESCRIPTION OF THE DRAWINGS

FIG. 1 is a diagram illustrating a layout of gate electrodes, source interconnects, and drain interconnects of a semiconductor device according to a first embodiment;

FIG. 2 is a cross-sectional view illustrating the semiconductor device according to the first embodiment;

FIG. 3 is a diagram illustrating a band structure of a semiconductor layer (regrown layer);

FIG. 4 is a cross-sectional view (part 1) illustrating a method of manufacturing the semiconductor device according to the first embodiment;

FIG. 5 is a cross-sectional view (part 2) illustrating the method of manufacturing the semiconductor device according to the first embodiment;

FIG. 6 is a cross-sectional view (part 3) illustrating the method of manufacturing the semiconductor device according to the first embodiment;

FIG. 7 is a cross-sectional view (part 4) illustrating the method of manufacturing the semiconductor device according to the first embodiment;

FIG. 8 is a cross-sectional view (part 5) illustrating the method of manufacturing the semiconductor device according to the first embodiment;

FIG. 9 is a cross-sectional view (part 6) illustrating the method of manufacturing the semiconductor device according to the first embodiment;

FIG. 10 is a cross-sectional view (part 7) illustrating the method of manufacturing the semiconductor device according to the first embodiment;

FIG. 11 is a cross-sectional view (part 8) illustrating the method of manufacturing the semiconductor device according to the first embodiment;

FIG. 12 is a cross-sectional view (part 9) illustrating the method of manufacturing the semiconductor device according to the first embodiment;

FIG. 13 is a cross-sectional view illustrating a semiconductor device according to a second embodiment;

FIG. 14 is a cross-sectional view (part 1) illustrating a method of manufacturing the semiconductor device according to the second embodiment;

FIG. 15 is a cross-sectional view (part 2) illustrating the method of manufacturing the semiconductor device according to the second embodiment; and

FIG. 16 is a cross-sectional view (part 3) illustrating the method of manufacturing the semiconductor device according to the second embodiment.

### DETAILED DESCRIPTION

### Description of Embodiments of Present Disclosure

In the related-art semiconductor device, there is a possibility that the contact resistance between the metal layer and the semiconductor layer increases, thereby resulting in a decrease in yield.

It is an object of an embodiment of the present disclosure to provide a semiconductor device and a method of manufacturing the semiconductor device that can improve yield.

According to an embodiment of the present disclosure, yield can be improved.

First, embodiments of the present disclosure will be listed and described.

[1] A semiconductor device according to one aspect of the present disclosure includes: a substrate having a first surface and a second surface opposite to the first surface; a first nitride semiconductor layer having a third surface in contact with the second surface, and a fourth surface opposite to the third surface, the first nitride semiconductor layer having a recess formed in the fourth surface; a second nitride semiconductor layer disposed in the recess; a first metal layer disposed on the second nitride semiconductor layer; and a third metal layer, wherein the first metal layer includes a second metal layer containing a platinum group metal, a through-hole is formed in the substrate, the first nitride semiconductor layer, and the second nitride semiconductor layer, and the through-hole penetrates the substrate, the first nitride semiconductor layer, and the second nitride semiconductor layer, and reaches the second metal layer, the third metal layer is in contact with the second metal layer and is configured to cover the first surface and an inner wall surface of the through-hole, and the second nitride semiconductor layer contains impurity atoms at a concentration of 1.0 × 10¹⁸ cm⁻³ or higher.

The second nitride semiconductor layer is formed in the recess formed in the fourth surface of the first nitride semiconductor layer, and the second nitride semiconductor layer contains impurity atoms at a concentration of 1.0 × 10¹⁸ cm⁻³ or higher. Therefore, an ohmic contact is obtained between the second nitride semiconductor layer and the first metal layer. Further, the second metal layer containing palladium has high resistance to a substance that may come into contact with the second metal layer between the formation of the through-hole and the formation of the third metal layer. Therefore, the stability of the electrical resistance between the third metal layer and the first nitride semiconductor layer is good, and yield can be improved.

[2] In [1], the second metal layer may contain palladium or platinum. In this case, the second metal layer easily functions as an etching stopper when the through-hole is formed, and the second metal layer has particularly high resistance to a substance that may come into contact with the second metal layer between the formation of the through-hole and the formation of the third metal layer.

[3] In [1] or [2], the first metal layer may include a fourth metal layer containing titanium between the second metal layer and the second nitride semiconductor layer, and the through-hole may penetrate the fourth metal layer. In this case, excellent adhesion is obtained between the second metal layer and the second nitride semiconductor layer.

[4] In any one of [1] to [3], the first metal layer may include a fifth metal layer covering the second metal layer, and an electrical resistance of the fifth metal layer may be lower than an electrical resistance of the second metal layer. In this case, the electrical resistance of the first metal layer including the second metal layer and the fifth metal layer can be easily reduced.

[5] In [4], the fifth metal layer may contain at least one selected from a group consisting of gold, copper, and aluminum. In this case, the electrical resistance of the fifth metal layer can be easily reduced.

[6] In any one of [1] to [5], the second nitride semiconductor layer may be a gallium nitride layer. In this case, a low electrical resistance can be easily obtained for the second nitride semiconductor layer.

[7] In any one of [1] to [6], a Fermi level may be higher than energy at a bottom of a conduction band in the second nitride semiconductor layer. In this case, an ohmic contact can be easily obtained between the second nitride semiconductor layer and the first metal layer.

[8] In any one of [1] to [7], a carrier density of the second nitride semiconductor layer may be higher than a carrier density of the first nitride semiconductor layer. In this case, the electrical resistance of the second nitride semiconductor layer can be easily reduced.

[9] A method of manufacturing a semiconductor device according to another aspect of the present disclosure includes: forming a first nitride semiconductor layer on a substrate having a first surface and a second surface opposite to the first surface, the first nitride semiconductor layer having a third surface in contact with the second surface, and a fourth surface opposite to the third surface; forming a recess in the fourth surface of the first nitride semiconductor layer; forming a second nitride semiconductor layer in the recess; forming, on the second nitride semiconductor layer, a first metal layer including a second metal layer containing a platinum group metal; forming a through-hole in the substate, the first nitride semiconductor layer, and the second nitride semiconductor layer, the through-hole penetrating the substrate, the first nitride semiconductor layer, and the second nitride semiconductor layer, and reaching the second metal layer; and forming a third metal layer in contact with the second metal layer and covering the first surface and an inner wall surface of the through-hole, wherein the second nitride semiconductor layer contains impurity atoms at a concentration of 1.0 × 10¹⁸ cm⁻³ or higher.

The recess is formed in the fourth surface of the first nitride semiconductor layer, the second nitride semiconductor layer is formed in the recess, and the second nitride semiconductor layer contains impurity atoms at a concentration of 1.0 × 10¹⁸ cm⁻³ or higher. Further, the second metal layer containing palladium has high resistance to a substance that may come into contact with the second metal layer between the formation of the through-hole and the formation of the third metal layer. Therefore, the stability of the electrical resistance between the third metal layer and the first nitride semiconductor layer is good, and yield can be improved.

### Details of Embodiments of Present Disclosure

Hereinafter, embodiments of the present disclosure will be described in detail, but the present disclosure is not limited thereto. In the present specification and the drawings, components having substantially the same functional configurations are denoted by the same reference numerals, and duplicate descriptions thereof may be omitted. Further, in the following description, an XYZ orthogonal coordinate system is used, but the XYZ coordinate system is defined for the sake of convenience of description and does not limit the orientation of a semiconductor device. Further, when viewed from an arbitrary point, the +Z side may be referred to as “above”, “upper side”, or “upward”, and the -Z side may be referred to as “below”, “lower side”, or “downward”.

### First Embodiment

A first embodiment will be described. The first embodiment relates to a semiconductor device including a GaN-based high electron mobility transistor (HEMT).

### Structure of Semiconductor Device

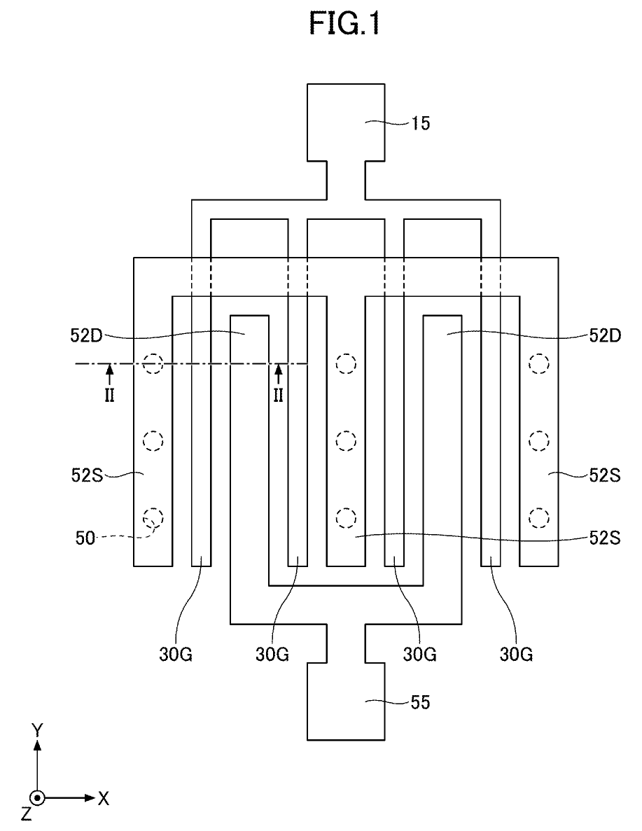

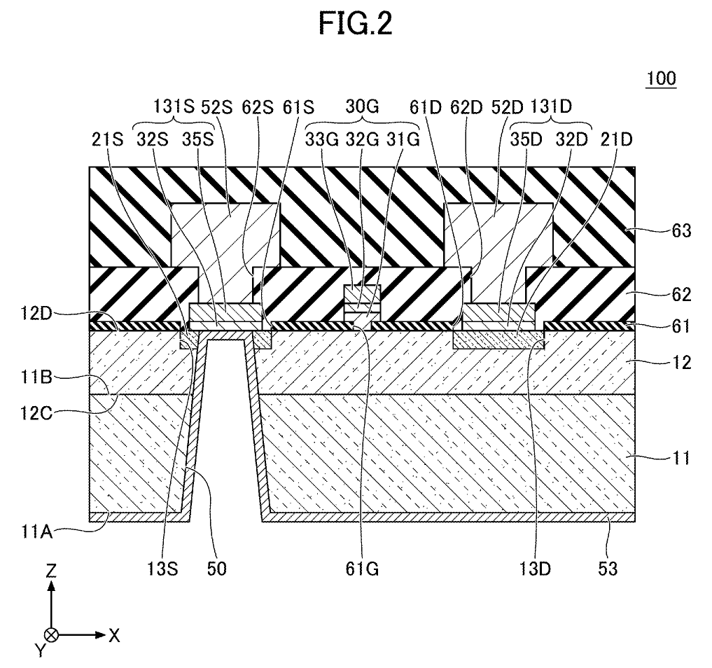

A structure of the semiconductor device according to the first embodiment will be described. FIG. 1 is a diagram illustrating a layout of gate electrodes, source interconnects, and drain interconnects of the semiconductor device according to the first embodiment. FIG. 2 is a cross-sectional view illustrating the semiconductor device according to the first embodiment. FIG. 2 corresponds to a cross-sectional view taken along the line II-II of FIG. 1.

As illustrated in FIG. 1 and FIG. 2, a semiconductor device 100 according to the first embodiment includes a substrate 11, a semiconductor layer 12, a semiconductor layer 21S, a semiconductor layer 21D, a gate electrode 30G, a source electrode 131S, a drain electrode 131D, a source interconnect 52S, a drain interconnect 52D, and a backside electrode 53.

The substrate 11 is, for example, a silicon carbide (SiC) substrate. The substrate 11 has a first surface 11A and a second surface 11B opposite to the first surface 11A. The second surface 11B is located above (on the +Z side of) the first surface 11A.

The semiconductor layer 12 is disposed on the substrate 11. The semiconductor layer 12 has a third surface 12C in contact with the second surface 11B, and has a fourth surface 12D opposite to the third surface 12C. The fourth surface 12D is located above (on the +Z side of) the third surface 12C. The semiconductor layer 12 is, for example, a nitride semiconductor layer containing gallium (Ga). The nitride semiconductor layer constitutes a portion of a high electron mobility transistor, such as an electron transport layer (a channel layer) or an electron supply layer (a barrier layer), and includes a two-dimensional electron gas (2DEG). The semiconductor layer 12 is an example of a first nitride semiconductor layer.

A plurality of recesses 13S and a plurality of recesses 13D are formed in the fourth surface 12D. The recesses 13S and 13D extend parallel to the Y-axis, and are alternately provided along the X-axis. For example, the recesses 13S and 13D reach the electron transport layer (the channel layer). The bottom surfaces of the recesses 13S and 13D may be located in the electron transport layer.

The semiconductor device 100 includes an insulating film 61. The insulating film 61 covers the fourth surface 12D of the semiconductor layer 12. For example, the insulating film 61 is a nitride film, such as a silicon nitride (SiN) film. A plurality of openings 61S, a plurality of openings 61D, and a plurality of openings 61G are formed in the insulating film 61. The openings 61S, 61D, and 61G penetrate the insulating film 61. The openings 61S, 61D, and 61G extend parallel to the Y-axis. An opening 61S is continuous with a recess 13S, and an opening 61D is continuous with a recess 13D. An opening 61G is provided between the opening 61S and the opening 61D that are adjacent to each other along the X-axis.

The semiconductor layer 21S is disposed in the recess 13S, and the semiconductor layer 21D is disposed in the recess 13D. A portion of the semiconductor layer 21S may be inside the opening 61S, and a portion of the semiconductor layer 21D may be inside the opening 61D. For example, the semiconductor layers 21S and 21D are gallium nitride (GaN) layers having an n-type conductivity. The semiconductor layers 21S and 21D are regrown layers. The carrier density of each of the semiconductor layers 21S and 21D is higher than the carrier density of the semiconductor layer 12. The semiconductor layers 21S and 21D contain n-type impurity atoms at a concentration of 1.0 × 10¹⁸ cm⁻³ or higher. The semiconductor layers 21S and 21D are, for example, degenerate semiconductor layers. The n-type impurity is, for example, silicon (Si) or germanium (Ge). The semiconductor layer 21S is an example of a second nitride semiconductor layer.

The gate electrode 30G extends parallel to the Y-axis. The gate electrode 30G is in Schottky contact with the semiconductor layer 12 through the opening 61G. The gate electrode 30G includes a metal layer 31G, a metal layer 32G, and a metal layer 33G. The metal layer 31G is in direct contact with the semiconductor layer 12. The metal layer 32G covers the metal layer 31G. The metal layer 33G covers the metal layer 32G. The metal layer 31G is located on the semiconductor layer 12 and the insulating film 61, the metal layer 32G is located on the metal layer 31G, and the metal layer 33G is located on the metal layer 32G. The metal layer 31G contains nickel (Ni). The metal layer 31G is, for example, a nickel (Ni) layer. The metal layer 32G contains palladium (Pd). The metal layer 32G is, for example, a palladium (Pd) layer. The metal layer 33G contains gold (Au). The metal layer 33G is, for example, a gold (Au) layer. As illustrated in FIG. 1, a plurality of gate electrodes 30G are connected to a gate common connection part 15.

The source electrode 131S extends parallel to the Y-axis. The source electrode 131S includes a metal layer 32S and a metal layer 35S. The metal layer 32S is in direct contact with the semiconductor layer 21S. The metal layer 35S covers the metal layer 32S. The metal layer 32S is located on the semiconductor layer 21S, and the metal layer 35S is located on the metal layer 32S. The metal layer 32S contains palladium (Pd). The metal layer 32S is, for example, a palladium (Pd) layer. The thickness of the metal layer 32S is, for example, 10 nm or more and 100 nm or less. The electrical resistance of the metal layer 35S is lower than the electrical resistance of the metal layer 32S. The metal layer 35S is, for example, a gold (Au) layer. The thickness of the metal layer 35S is, for example, 200 nm or more and 1,000 nm or less. The source electrode 131S is an example of a first metal layer. The metal layer 32S is an example of a second metal layer. The metal layer 35S is an example of a fifth metal layer.

The drain electrode 131D extends parallel to the Y-axis. The drain electrode 131D includes a metal layer 32D and a metal layer 35D. The metal layer 32D is in direct contact with the semiconductor layer 21D. The metal layer 35D covers the metal layer 32D. The metal layer 32D is located on the semiconductor layer 21D, and the metal layer 35D is located on the metal layer 32D. The metal layer 32D contains palladium (Pd). The metal layer 32D is, for example, a palladium (Pd) layer. The thickness of the metal layer 32D is, for example, 10 nm or more and 100 nm or less. The electrical resistance of the metal layer 35D is lower than the electrical resistance of the metal layer 32D. The metal layer 35D is, for example, a gold (Au) layer. The thickness of the metal layer 35D is, for example, 200 nm or more and 1,000 nm or less.

The semiconductor device 100 includes an insulating film 62. The insulating film 62 covers the semiconductor layer 21S, the semiconductor layer 21D, the source electrode 131S, the drain electrode 131D, the gate electrode 30G, and the insulating film 61. For example, the insulating film 62 is a nitride film such as a silicon nitride (SiN) film. A plurality of openings 62S and a plurality of openings 62D are formed in the insulating film 62. An opening 62S and an opening 62D extend parallel to the Y-axis. The opening 62S reaches the source electrode 131S, and the opening 62D reaches the drain electrode 131D.

The source interconnect 52S is located over the source electrode 131S. The source interconnect 52S is disposed on the insulating film 62. The source interconnect 52S is in contact with the source electrode 131S through the opening 62S. The drain interconnect 52D is located over the drain electrode 131D. The drain interconnect 52D is disposed on the insulating film 62. The drain interconnect 52D is in contact with the drain electrode 131D through the opening 62D. Each of the source interconnect 52S and the drain interconnect 52D includes, for example, a seed layer and a plating layer on the seed layer. For example, the seed layer includes a titanium (Ti) layer, and the plating layer includes a gold (Au) layer. As illustrated in FIG. 1, a plurality of drain interconnects 52D may be connected to a drain pad 55, and a plurality of source interconnects 52S may be connected to each other.

The semiconductor device 100 includes an insulating film 63. The insulating film 63 covers the source interconnect 52S, the drain interconnect 52D, and the insulating film 62. For example, the insulating film 63 is a nitride film such as a silicon nitride (SiN) film.

Although not illustrated, an opening reaching the gate common connection part 15 is formed in the insulating film 62, and a gate pad in contact with the gate common connection part 15 through this opening is formed on the insulating film 62. In addition, an opening reaching the gate pad and an opening reaching the drain pad 55 are formed in the insulating film 63.

A through-hole 50 penetrating the substrate 11, the semiconductor layer 12, and the semiconductor layer 21S is formed in the substrate 11, the semiconductor layer 12, and the semiconductor layer 21S. The through-hole 50 reaches the source electrode 131S. The through-hole 50 reaches the metal layer 32S. At least one through-hole 50 is formed with respect to all source electrodes 131S. A plurality of through-holes 50 may be formed for each of a plurality of source electrode 131S. There may be source electrodes 131S for which through-holes 50 are formed and source electrodes 131S for which through-holes 50 are not formed.

The backside electrode 53 is formed on the lower surface of the metal layer 32S of the source electrode 131S, the inner wall surface of the through-hole 50, and the lower surface (first surface 11A) of the substrate 11. The backside electrode 53 is in contact with the metal layer 32S of the source electrode 131S, and covers the first surface 11A and the inner wall surface of the through-hole 50. The backside electrode 53 includes, for example, a seed layer and a plating layer. For example, the seed layer includes a titanium (Ti) layer, a nickel (Ni) layer, a nickel-chromium (NiCr) alloy layer, or a tantalum (Ta) layer, and the plating layer includes a gold (Au) layer. The backside electrode 53 is an example of a third metal layer.

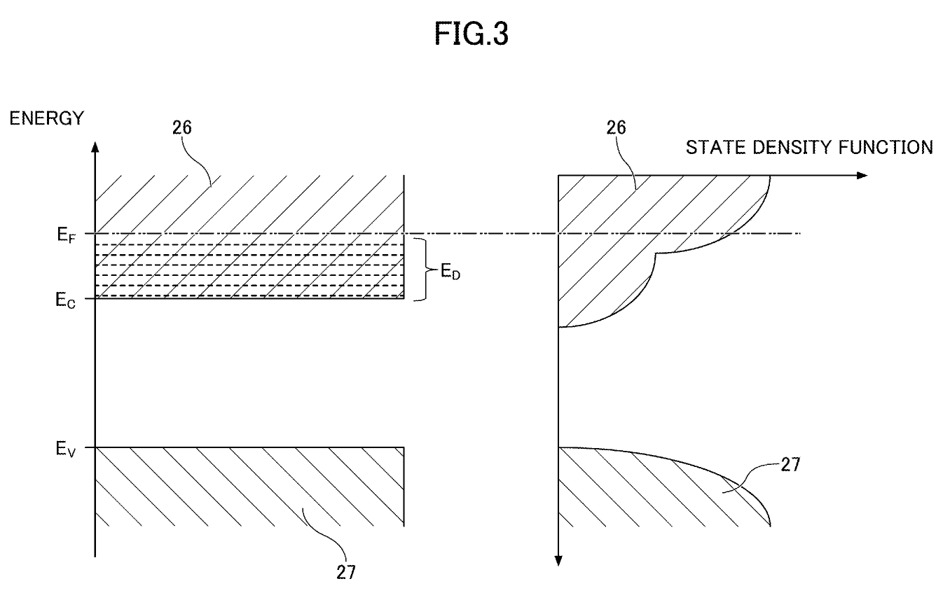

In the semiconductor device 100, the semiconductor layer 21S is formed in the recess 13S of the semiconductor layer 12, and the semiconductor layer 21S contains impurity atoms at a concentration of 1.0 × 10¹⁸ cm⁻³ or higher. In such a semiconductor layer 21S, the distance between the impurity atoms is short, and as illustrated in FIG. 3, a binding band in which the impurity levels (E_{D}) interact with each other is formed, and the binding band is connected to a conduction band 26. At this time, because the Fermi level (E_{F}) is present in the conduction band, that is, the Fermi level (E_{F}) is higher than energy (E_{c}) at the bottom of the conduction band, the semiconductor layer 21S exhibits properties similar to properties of metal. That is, the semiconductor layer 21S functions as a degenerate semiconductor layer. Accordingly, an ohmic contact is obtained between the semiconductor layer 21S and the source electrode 131S. FIG. 3 is a diagram illustrating a band structure of the semiconductor layer 21S. In FIG. 3, E_{V} indicates energy at the top of a valence band 27.

### Method of Manufacturing Semiconductor Device

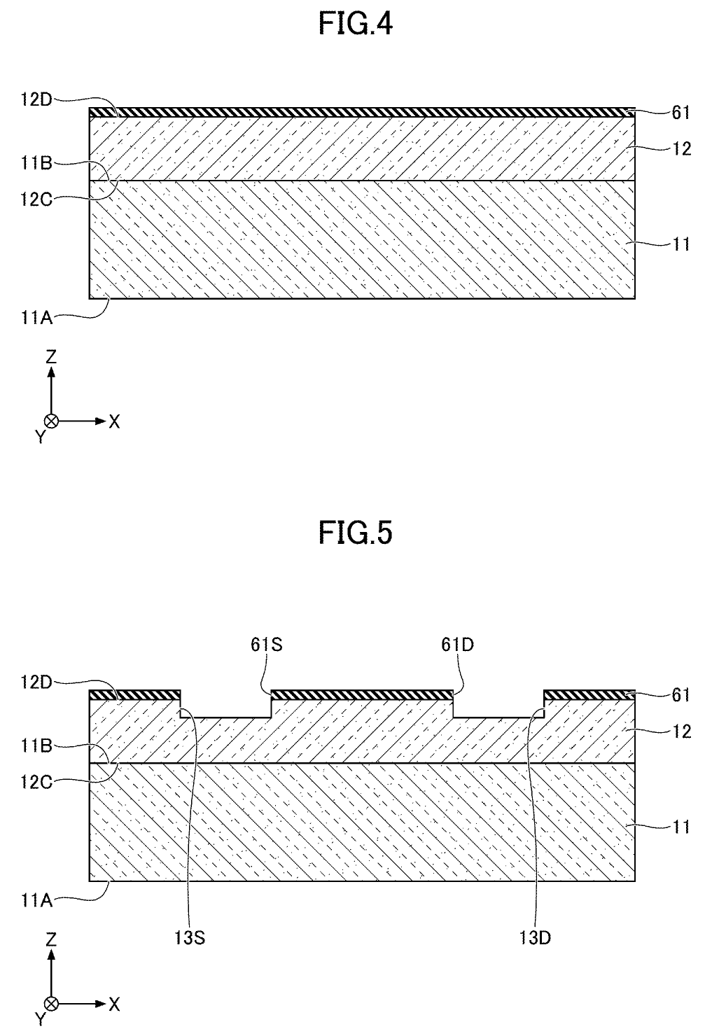

Next, a method of manufacturing the semiconductor device 100 according to the first embodiment will be described. FIG. 4 to FIG. 12 are cross-sectional views illustrating the method of manufacturing the semiconductor device 100 according to the first embodiment.

As illustrated in FIG. 4, the semiconductor layer 12 is formed on the substrate 11 by, for example, a metal organic chemical vapor deposition (MOCVD) method. The substrate 11 has the first surface 11A and the second surface 11B opposite to the first surface 11A. The semiconductor layer 12 has the third surface 12C in contact with the second surface 11B, and the fourth surface 12D opposite to the third surface 12C. Next, the insulating film 61 is formed on the semiconductor layer 12. The insulating film 61 can be formed by, for example, a plasma CVD method. The insulating film 61 covers the fourth surface 12D of the semiconductor layer 12.

Next, as illustrated in FIG. 5, the openings 61S and 61D are formed in the insulating film 61, and the recesses 13S and 13D are formed in the semiconductor layer 12. In the formation of the openings 61S and 61D, for example, reactive ion etching (RIE) of the insulating film 61 is performed using a resist pattern as a mask. When the RIE of the insulating film 61 is performed, a reactive gas containing fluorine (F) is used, for example. In the formation of the recesses 13S and 13D, RIE of the semiconductor layer 12 is performed using the resist pattern used in the formation of the openings 61S and 61D as a mask. When the RIE of the semiconductor layer 12 is performed, a reactive gas containing chlorine (Cl) is used, for example.

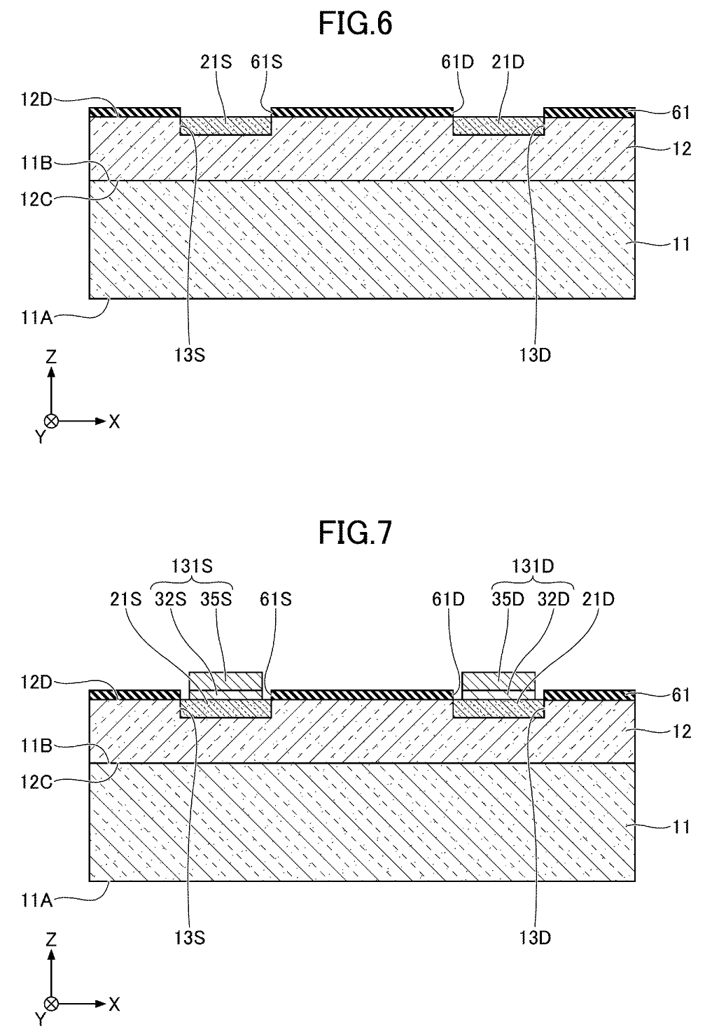

Next, as illustrated in FIG. 6, the semiconductor layer 21S is formed in the recess 13S, and the semiconductor layer 21D is formed in the recess 13D. In the formation of the semiconductor layers 21S and 21D, crystal growth of the semiconductor layers is performed by, for example, a MOCVD method, a molecular beam epitaxy (MBE) method, or a sputtering method using a growth mask, and then the growth mask is removed. The semiconductor layers 21S and 21D are what are known as regrown layers.

Next, as illustrated in FIG. 7, the source electrode 131S is formed on the semiconductor layer 21S, and the drain electrode 131D is formed on the semiconductor layer 21D. The source electrode 131S includes the metal layers 32S and 35S, and the drain electrode 131D includes the metal layers 32D and 35D. The source electrode 131S and the drain electrode 131D can be formed by, for example, vapor deposition using a growth mask and lift-off.

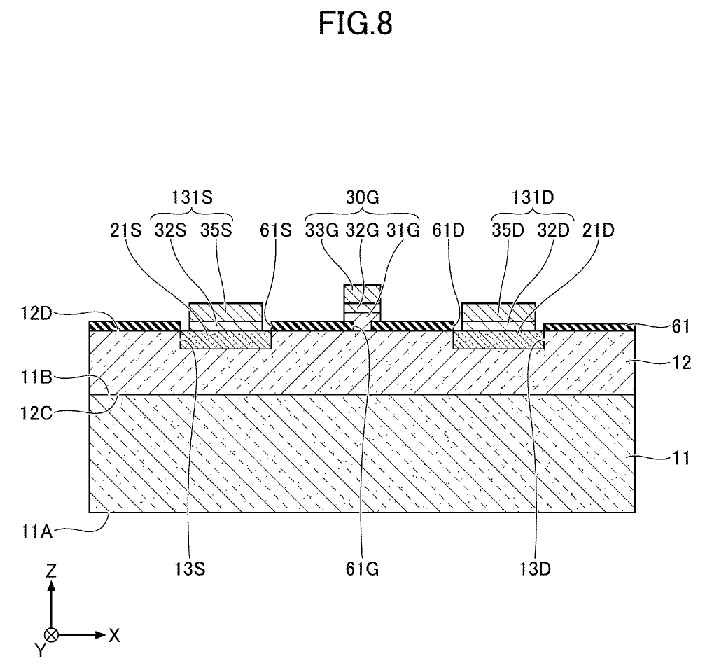

Next, as illustrated in FIG. 8, the opening 61G is formed in the insulating film 61. In the formation of the opening 61G, for example, RIE using a resist pattern as a mask is performed. A reactive gas containing fluorine (F) is used to etch the insulating film 61, for example. Next, the gate electrode 30G is formed on the semiconductor layer 12 and the insulating film 61. The gate electrode 30G includes the metal layers 31G, 32G, and 33G. The gate electrode 30G can be formed by, for example, vapor deposition using a growth mask and lift-off. The gate electrode 30G is in Schottky contact with the semiconductor layer 12 through the opening 61G.

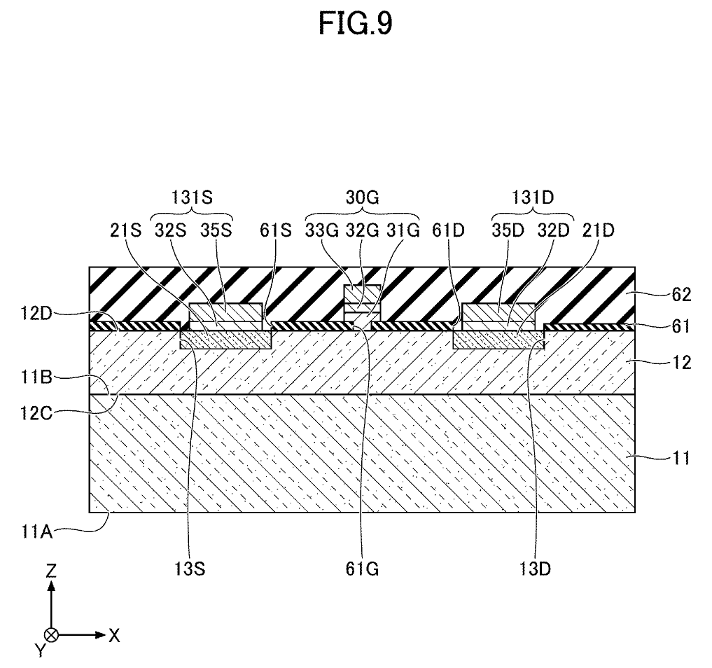

Next, as illustrated in FIG. 9, the insulating film 62 is formed on the semiconductor layer 21S, the semiconductor layer 21D, the source electrode 131S, the drain electrode 131D, the gate electrode 30G, and the insulating film 61. The insulating film 62 can be formed by, for example, a plasma CVD method. The insulating film 62 covers the semiconductor layer 21S, the semiconductor layer 21D, the source electrode 131S, the drain electrode 131D, the gate electrode 30G, and the insulating film 61.

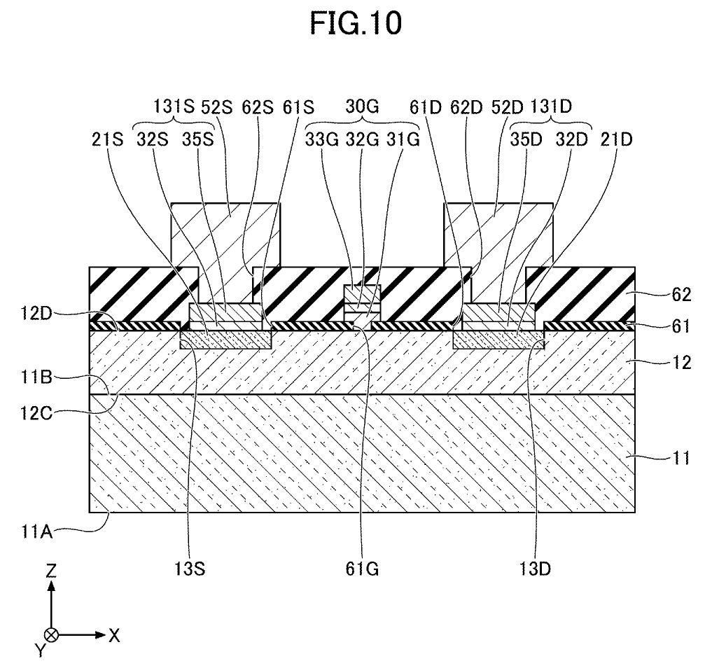

Next, as illustrated in FIG. 10, the openings 62S and 62D are formed in the insulating film 62. In the formation of the openings 62S and 62D, RIE of the insulating film 62 is performed using a resist pattern as a mask, for example. When the RIE of the insulating film 62 is performed, a reactive gas containing fluorine (F) is used, for example. Next, the source interconnect 52S, in contact with the source electrode 131S through the opening 62S, and the drain interconnect 52D, in contact with the drain electrode 131D through the opening 62D, are formed on the insulating film 62.

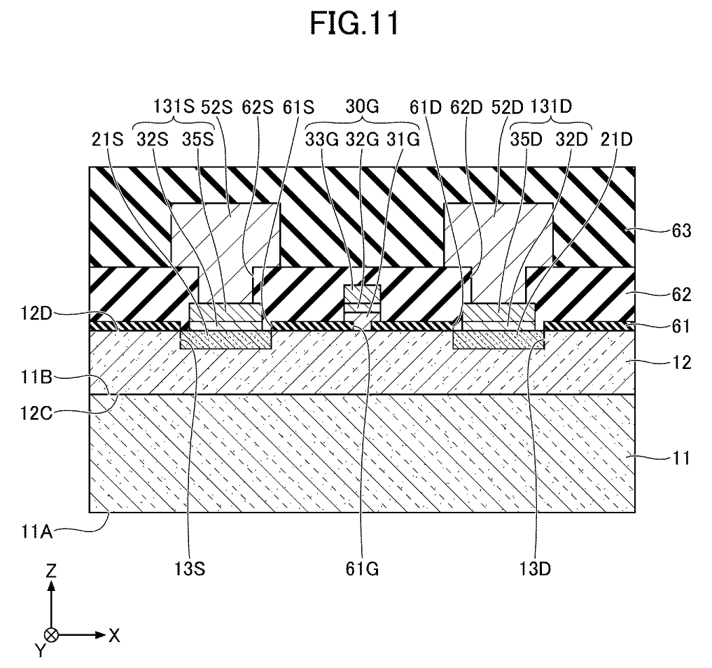

Next, as illustrated in FIG. 11, the insulating film 63 is formed on the insulating film 62. The insulating film 63 can be formed by, for example, a plasma CVD method. The insulating film 63 covers the source interconnect 52S, the drain interconnect 52D, and the insulating film 62.

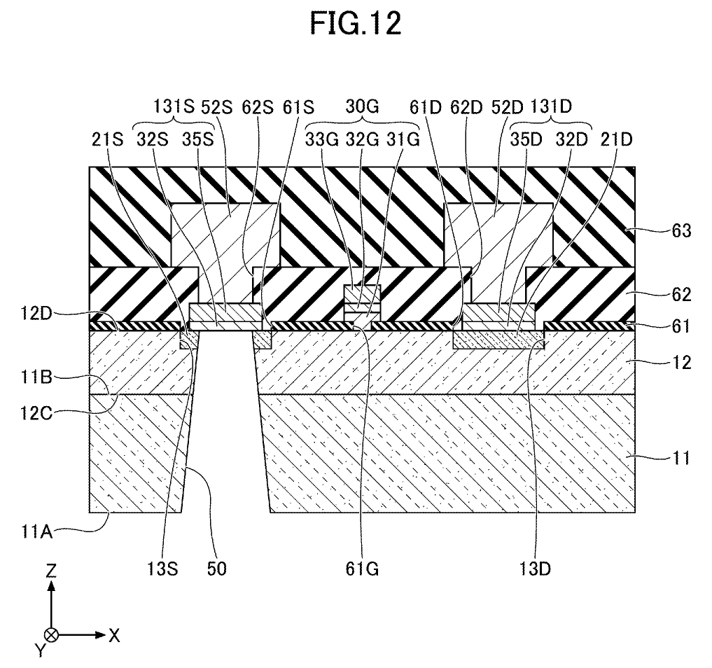

Next, as illustrated in FIG. 12, the through-hole 50 penetrating the substrate 11, the semiconductor layer 12, and the semiconductor layer 21S is formed in the substrate 11, the semiconductor layer 12, and the semiconductor layer 21S. The through-hole 50 is formed so as to reach the source electrode 131S. In the formation of the through-hole 50, the semiconductor layers 12 and 21S are etched after the substrate 11 is etched. When the semiconductor layers 12 and 21S are etched, a reactive gas containing chlorine (Cl) is used, for example. The metal layer 32S containing palladium (Pd) has high resistance to etching using a reactive gas containing chlorine (Cl). Therefore, the metal layer 32S functions as an etching stopper, and the lower surface of the metal layer 32S is exposed in the through-hole 50. When the substrate 11 is etched so as to form the through-hole 50, a mask is formed on the first surface 11A, and the mask is removed after the substrate 11 is etched. Further, after the through-hole 50 is formed, the inside of the through-hole 50 is cleaned.

Next, the backside electrode 53 is formed (see FIG. 2). The backside electrode 53 is in contact with the metal layer 32S of the source electrode 131S, and covers the first surface 11A and the inner wall surface of the through-hole 50.

In this manner, the semiconductor device 100 according to the first embodiment can be manufactured.

In the semiconductor device 100, the backside electrode 53 is in contact with the source electrode 131S, and the source electrode 131S and the semiconductor layer 21S are in ohmic contact with each other. For this reason, the electrical resistance between the semiconductor layer 12 including the 2DEG and the backside electrode 53 is low. Therefore, according to the semiconductor device 100, the stability of the electrical resistance between the backside electrode 53 and the semiconductor layer 12 is good, and thus yield can be improved.

It is conceivable to use a nickel (Ni) layer as an etching stopper when the semiconductor layers 12 and 21S are etched, but nickel may react with a substance used to remove the mask after the substrate 11 is etched and a substance used to clean the inside of the through-hole 50. For this reason, if the nickel (Ni) layer is used as an etching stopper, a partial loss of the etching stopper is likely to occur, thereby resulting in an increase in the contact resistance between the source electrode 131S and the semiconductor layer 21S and a reduction in yield. In contrast, in the semiconductor device 100, the metal layer 32S contains palladium (Pd), and the metal layer 32S has high resistance to a substance used to remove the mask after the substrate 11 is etched and to a substance used to clean the inside of the through hole 50. Accordingly, an increase in the contact resistance as in the case where the nickel (Ni) layer is used does not occur, and yield can be improved.

The metal layer 32S contains a platinum group metal, but the platinum group metal is not limited to palladium (Pd). For example, the metal layer 32S may contain platinum (Pt), and the metal layer 32S may be a platinum (Pt) layer. When the metal layer 32S contains palladium (Pd) or platinum (Pt), the metal layer 32S easily functions as an etching stopper when the through-hole 50 is formed, and exhibits particularly high resistance to a substance used to remove the mask and to a substance used to clean the inside of the through-hole 50. The metal layer 32D may contain a platinum group metal other than palladium (Pd). For example, the metal layer 32D may contain platinum (Pt), and the metal layer 32D may be a platinum (Pt) layer.

When the semiconductor layer 21S is a GaN layer, a low electrical resistance can be easily obtained for the semiconductor layer 21S,

The carrier density of each of the semiconductor layers 21S and 21D is higher than the carrier density of the semiconductor layer 12. Thus, the electrical resistance of the semiconductor device 100 can be easily reduced. Specifically, the electrical resistance between the backside electrode 53 and the drain interconnect 52D can be easily reduced.

The semiconductor layer 21S may contain n-type impurity atoms at a concentration of 1.0 × 10¹⁹ cm⁻³ or higher, or may contain n-type impurity atoms at a concentration of 1.0 × 10²⁰ cm⁻³ or higher. The higher the concentration of the n-type impurity atoms in the semiconductor layer 21S, the easier it is to obtain an ohmic contact with the source electrode 131S. Similarly, the semiconductor layer 21D may contain n-type impurity atoms at a concentration of 1.0 × 10¹⁹ cm⁻³ or higher, or may contain n-type impurity atoms at a concentration of 1.0 × 10²⁰ cm⁻³ or higher. The higher the concentration of the n-type impurity atoms in the semiconductor layer 21D, the easier it is to obtain an ohmic contact with the drain electrode 131D. The concentration of impurity atoms can be measured by secondary ion mass spectrometry (SIMS).

Because the source electrode 131S includes the metal layer 35S and the electrical resistance of the metal layer 35S is lower than the electrical resistance of the metal layer 32S, the electrical resistance of the source electrode 131S can be reduced. Because the drain electrode 131D includes the metal layer 35D and the electrical resistance of the metal layer 35D is lower than the electrical resistance of the metal layer 32D, the electrical resistance of the drain electrode 131D can be reduced. The metal layers 35S and 35D are not limited to gold (Au) layers. The metal layers 35S and 35D may contain at least one selected from the group consisting of gold (Au), copper (Cu), and aluminum (Al).

### Second Embodiment

A second embodiment will be described. The second embodiment differs from the first embodiment mainly in configurations of a source electrode and a drain electrode.

### Structure of Semiconductor Device

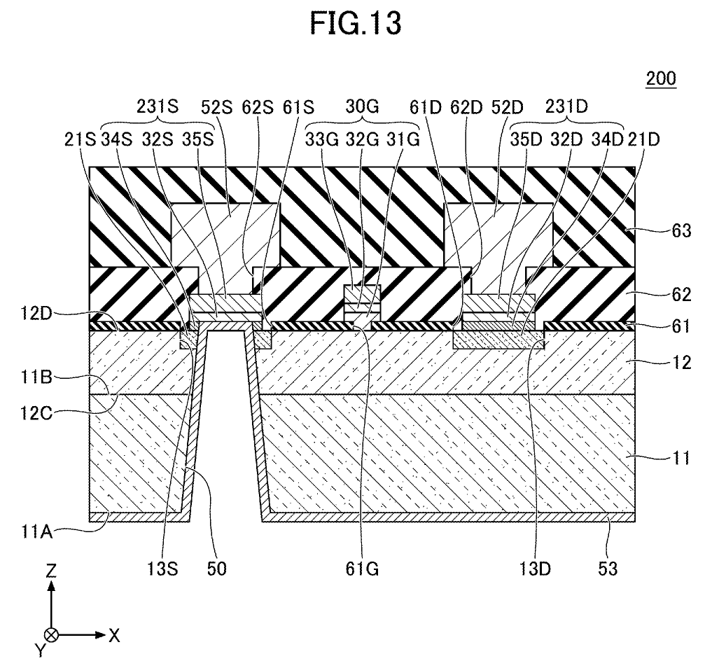

A structure of a semiconductor device according to the second embodiment will be described. FIG. 13 is a cross-sectional view illustrating the semiconductor device according to the second embodiment.

As illustrated in FIG. 13, a semiconductor device 200 according to the second embodiment includes a source electrode 231S instead of the source electrode 131S, and a drain electrode 231D instead of the drain electrode 131D.

The source electrode 231S extends parallel to the Y-axis. The source electrode 231S includes a metal layer 34S, the metal layer 32S, and the metal layer 35S. The metal layer 34S is directly in contact with the semiconductor layer 21S. The metal layer 32S covers the metal layer 34S. The metal layer 35S covers the metal layer 32S. The metal layer 34S is located on the semiconductor layer 21S, the metal layer 32S is located on the metal layer 34S, and the metal layer 35S is located on the metal layer 32S. The metal layer 34S is located between the metal layer 32S and the semiconductor layer 21S. The metal layer 34S contains titanium (Ti). The metal layer 34S is, for example, a titanium (Ti) layer. The thickness of the metal layer 34S is, for example, 3 nm or more and 50 nm or less. The metal layer 34S is an example of a fourth metal layer.

The drain electrode 231D extends parallel to the Y-axis. The drain electrode 231D includes a metal layer 34D, the metal layer 32D, and the metal layer 35D. The metal layer 34D is in direct contact with the semiconductor layer 21D. The metal layer 32D covers the metal layer 34D. The metal layer 35D covers the metal layer 32D. The metal layer 34D is located on the semiconductor layer 21D, the metal layer 32D is located on the metal layer 34D, and the metal layer 35D is located on the metal layer 32D. The metal layer 34D is located between the metal layer 32D and the semiconductor layer 21D. The metal layer 34D contains titanium (Ti). The metal layer 34D is, for example, a titanium (Ti) layer. The thickness of the metal layer 34D is, for example, 3 nm or more and 50 nm or less.

The through-hole 50 penetrates the substrate 11, the semiconductor layer 12, the semiconductor layer 21S, and the metal layer 34S, and reaches the metal layer 32S. The backside electrode 53 is formed on the lower surface of the metal layer 32S, the inner wall surface of the through-hole 50, and the lower surface (first surface 11A) of the substrate 11. The backside electrode 53 is in contact with the metal layer 32S of the source electrode 231S.

Other configurations of the semiconductor device 200 are the same as those of the semiconductor device 100.

### Method of Manufacturing Semiconductor Device

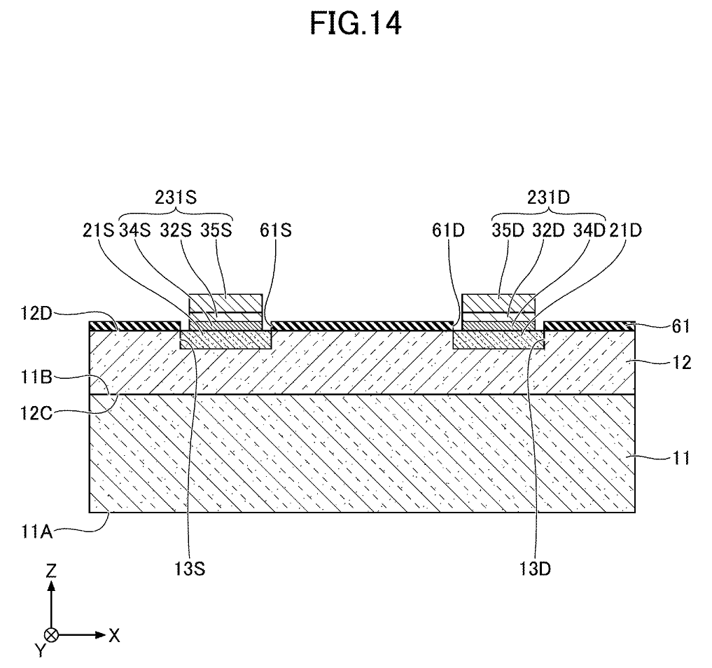

Next, a method of manufacturing the semiconductor device 200 according to the second embodiment will be described. FIG. 14 to FIG. 16 are cross-sectional views illustrating the method of manufacturing the semiconductor device 200 according to the second embodiment.

The processes up to the formation of the semiconductor layers 21S and 21D are performed in the same manner as in the first embodiment (see FIG. 6). Next, as illustrated in FIG. 14, the source electrode 231S is formed on the semiconductor layer 21S, and the drain electrode 231D is formed on the semiconductor layer 21D. The source electrode 231S includes the metal layers 34S, 32S, and 35S, and the drain electrode 231D includes the metal layers 34D, 32D, and 35D. The source electrode 231S and the drain electrode 231D can be formed by, for example, vapor deposition using a growth mask and lift-off.

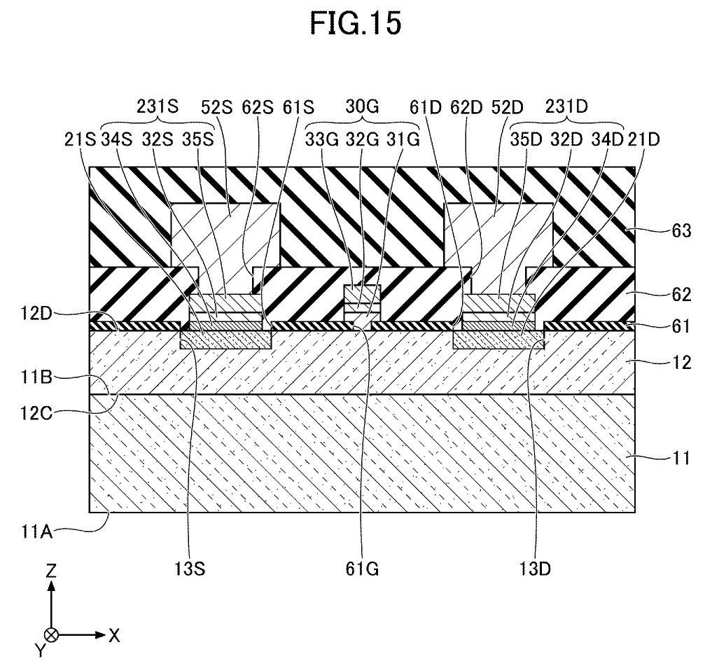

Next, as illustrated in FIG. 15, the processes from the formation of the opening 61G to the formation of the insulating film 63 are performed in the same manner as in the first embodiment.

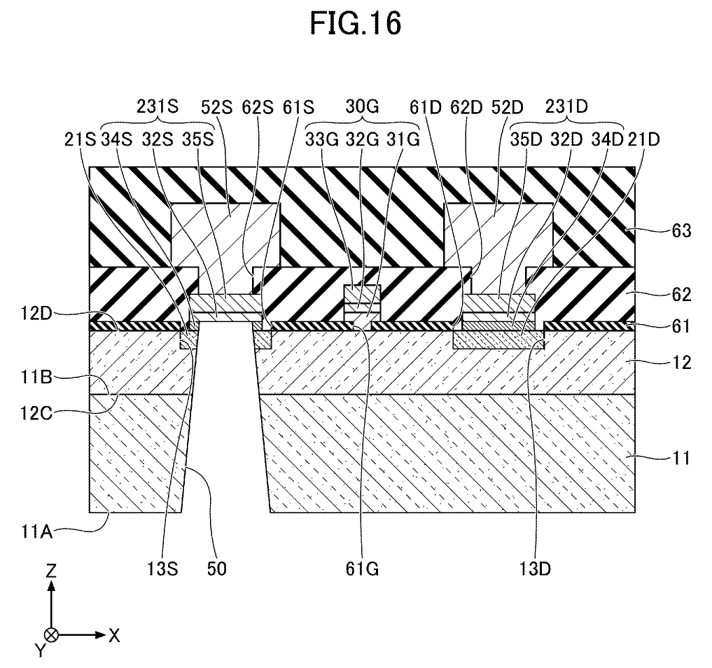

Next, as illustrated in FIG. 16, the through-hole 50 penetrating the substrate 11, the semiconductor layer 12, and the semiconductor layer 21S is formed in the substrate 11, the semiconductor layer 12, and the semiconductor layer 21S. The through-hole 50 is formed so as to reach the source electrode 231S. In the formation of the through-hole 50, the semiconductor layers 12 and 21S are etched after the substrate 11 is etched. When the semiconductor layers 12 and 21S are etched, a reactive gas containing chlorine (Cl) is used, for example. The metal layer 34S containing titanium (Ti) has low resistance to etching using a reactive gas containing chlorine (Cl), and the through-hole 50 penetrates the metal layer 34S. Further, the metal layer 32S containing palladium (Pd) has high resistance to etching using a reactive gas containing chlorine (Cl). Therefore, the metal layer 32S functions as an etching stopper, and the lower surface of the metal layer 32S is exposed in the through-hole 50. When the substrate 11 is etched so as to form the through-hole 50, a mask is formed on the first surface 11A, and the mask is removed after the substrate 11 is etched. Further, after the through-hole 50 is formed, the inside of the through-hole 50 is cleaned.

Next, the backside electrode 53 is formed (see FIG. 13). The backside electrode 53 is in contact with the metal layer 32S of the source electrode 231S, and covers the first surface 11A and the inner wall surface of the through-hole 50.

In this manner, the semiconductor device 200 according to the second embodiment can be manufactured.

Similarly to the first embodiment, according to the second embodiment, yield can be improved. That is, in the semiconductor device 200, the backside electrode 53 is in contact with the source electrode 231S, and the source electrode 231S and the semiconductor layer 21S are in ohmic contact with each other. Therefore, the electrical resistance between the semiconductor layer 12 including the 2DEG and the backside electrode 53 is low. Further, similar to the metal layer 32S, the metal layer 34S containing titanium (Ti) also has high resistance to a substance used to remove the mask after the substrate 11 is etched and to a substance used to clean the inside of the through-hole 50. Therefore, according to the semiconductor device 200, the stability of the electrical resistance between the backside electrode 53 and the semiconductor layer 12 is good, and thus yield can be improved.

Further, in the semiconductor device 200, the source electrode 231S includes the metal layer 34S containing titanium (Ti) between the metal layer 32S and the semiconductor layer 21S. The metal layer 34S has high adhesion between the metal layer 32S and the semiconductor layer 21S. Therefore, excellent adhesion can be obtained between the metal layer 32S and the semiconductor layer 21S.

Although embodiments have been described in detail, the present disclosure is not limited to the specific embodiments, and various modifications and changes can be made within the scope described in the claims.

What is claimed is:

1. A semiconductor device comprising:
a substrate having a first surface and a second surface opposite to the first surface;
a first nitride semiconductor layer having a third surface in contact with the second surface, and a fourth surface opposite to the third surface, the first nitride semiconductor layer having a recess formed in the fourth surface;
a second nitride semiconductor layer disposed in the recess;
a first metal layer disposed on the second nitride semiconductor layer; and
a third metal layer,
wherein
the first metal layer includes a second metal layer containing a platinum group metal,
a through-hole is formed in the substrate, the first nitride semiconductor layer, and the second nitride semiconductor layer, and the through-hole penetrates the substrate, the first nitride semiconductor layer, and the second nitride semiconductor layer, and reaches the second metal layer,
the third metal layer is in contact with the second metal layer and is configured to cover the first surface and an inner wall surface of the through-hole, and
the second nitride semiconductor layer contains impurity atoms at a concentration of 1.0 × 10¹⁸ cm⁻³ or higher.

2. The semiconductor device according to claim 1, wherein the second metal layer contains palladium or platinum.

3. The semiconductor device according to claim 1, wherein
the first metal layer includes a fourth metal layer containing titanium between the second metal layer and the second nitride semiconductor layer, and
the through-hole is configured to penetrate the fourth metal layer.

4. The semiconductor device according to claim 1, wherein
the first metal layer includes a fifth metal layer covering the second metal layer, and
an electrical resistance of the fifth metal layer is lower than an electrical resistance of the second metal layer.

5. The semiconductor device according to claim 4, wherein the fifth metal layer contains at least one selected from a group consisting of gold, copper, and aluminum.

6. The semiconductor device according to claim 1, wherein the second nitride semiconductor layer is a gallium nitride layer.

7. The semiconductor device according to claim 1, wherein a Fermi level is higher than energy at a bottom of a conduction band in the second nitride semiconductor layer.

8. The semiconductor device according to claim 1, wherein a carrier density of the second nitride semiconductor layer is higher than a carrier density of the first nitride semiconductor layer.

9. A method of manufacturing a semiconductor device, the method comprising:
forming a first nitride semiconductor layer on a substrate having a first surface and a second surface opposite to the first surface, the first nitride semiconductor layer having a third surface in contact with the second surface, and a fourth surface opposite to the third surface;
forming a recess in the fourth surface of the first nitride semiconductor layer;
forming a second nitride semiconductor layer in the recess;
forming, on the second nitride semiconductor layer, a first metal layer including a second metal layer containing a platinum group metal;
forming a through-hole in the substate, the first nitride semiconductor layer, and the second nitride semiconductor layer, the through-hole penetrating the substrate, the first nitride semiconductor layer, and the second nitride semiconductor layer, and reaching the second metal layer; and
forming a third metal layer in contact with the second metal layer and covering the first surface and an inner wall surface of the through-hole, wherein
the second nitride semiconductor layer contains impurity atoms at a concentration of 1.0 × 10¹⁸ cm⁻³ or higher.
